(19) United States
(12) Patent Application Publication
(10) Pub. No.: US 2008/0123437 A1
(43) Pub. Date: May 29, 2008

(54) Apparatus for Floating Bitlines in Static Random Access Memory Arrays

(76) Inventors: Vikas Agarwal, Austin, TX (US); Sam G. Chu, Round Rock, TX (US); Jose A. Paredes, Austin, TX (US)

Correspondence Address: DILLON & YUDELL LLP, 8911 N. CAPITAL OF TEXAS HWY.,, SUITE 2110, AUSTIN, TX, 78759, US

(21) Appl. No.: 11/564,697

(22) Filed: Nov. 29, 2006

(51) Int. Cl. G11C 7/12

(52) U.S. Cl. 365/189.02

(57) ABSTRACT

An apparatus for floating read bitlines of a static random access memory (SRAM) is disclosed. The SRAM includes a first and second SRAM cell columns, a first and second read bitlines, and a multiplexor. The multiplexor is coupled to the first and second SRAM cell columns via the first and second read bitlines, respectively. The multiplexor is capable of selectively transmitting data from the first or second SRAM cell column via the first or second read bitline, respectively, to an output. In addition, the multiplexor allows the first read bitline and/or the second read bitline to remain uncharged when no data are being read from the first SRAM cell column and/or the second SRAM cell column.

### BACKGROUND OF THE INVENTION

1. Technical Field

The present invention relates to memory devices in general, and more particularly, to a method and apparatus for reducing power consumption in memory devices. Still more particularly, the present invention relates to an apparatus for floating bitlines in static random access memories.

2. Description of Related Art

Static random access memory (SRAM) is a form of volatile semiconductor memory. Typically, multiple SRAM cells are interconnected to each other to form a memory array. Wordlines and bitlines are commonly utilized to access SRAM cells within a SRAM array.

One common SRAM design is to have two SRAM arrays connected to a multiplexor via respective read bitlines. In order to drive a global bitline, the signal of one of two read bitlines, which are coupled to the input of a multiplexor, needs to be pulled up. Since at least one wordline must constantly be active, conventional SRAM arrays have relatively high power consumption levels.

An alternative method of pulling up the signal of one of the two read bitlines is to pre-charge both read bitlines that enter each multiplexor. However, pre-charging bitlines requires more circuitry and still consumes a lot of power.

Consequently, it would be desirable to provide an improved apparatus for enabling the read bitlines of an SRAM array to float (i.e., remain uncharged) during a standby mode.

### SUMMARY OF THE INVENTION

In accordance with a preferred embodiment of the present invention, a static random access memory (SRAM) includes a first and second SRAM cell columns, a first and second read bitlines, and a multiplexor. The multiplexor is coupled to the first and second SRAM cell columns via the first and second read bitlines, respectively. The multiplexor is capable of selectively transmitting data from the first or second SRAM cell column via the first or second read bitline, respectively, to an output. In addition, the multiplexor allows the first read bitline and/or the second read bitline to remain uncharged when no data are being read from the first SRAM cell column and/or the second SRAM cell column.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is an electronic system having a memory device in which a preferred embodiment of the present invention is incorporated;

FIG. 2 is a block diagram of a bit column within a static random access memory array of the memory device from FIG. 1, in accordance with a preferred embodiment of the present invention; and

FIG. 3 is a schematic diagram of a multiplexor circuit within the static random access memory array of FIG. 2, in accordance with a preferred embodiment of the invention.

### DETAILED DESCRIPTION OF A PREFERRED EMBODIMENT

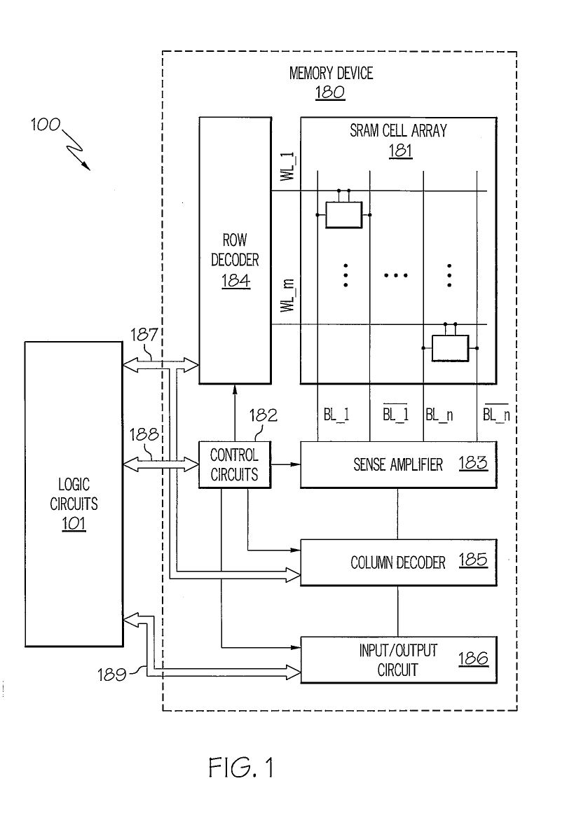

Referring now to the drawings, and specifically to FIG. 1, there is an electronic system having a memory device in which a preferred embodiment of the present invention is incorporated. As shown, an electronic system 100 includes a set of logic circuits 101 coupled to a memory device 180. Specifically, logic circuits 101 are coupled to a row decoder 184 and a column decoder 185 of memory device 180 via address lines 187. Logic circuits 101 are also coupled to a control circuit 182 of memory device 180 via control lines 188. In addition, logic circuits 101 are coupled to an input/output circuit 186 of memory device 180 via input/output lines 189.

Memory device 180 includes a sense amplifier 183 and a static random access memory (SRAM) cell array 181. SRAM cell array 181 includes a number of wordlines (i.e., WL_1 through WL_m) and a number of bitline pairs (i.e., BL_1 through BL_n and B̅L̅_1 through B̅L̅_n). Along with sense amplifier 183, SRAM cell array 181 is constructed to use a memory cell sensing scheme such that each bitline pair is to be used in reading and writing data into SRAM cell array 181.

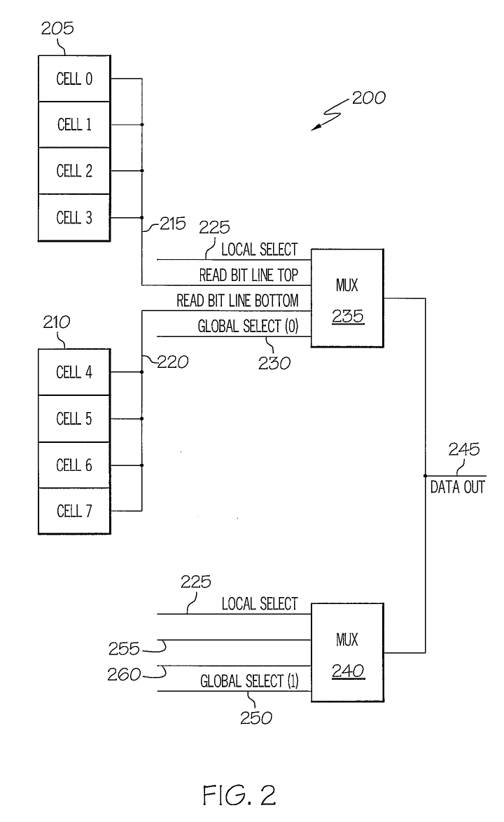

With reference now to FIG. 2, there is depicted a block diagram of a bit column within SRAM cell array 181, in accordance with a preferred embodiment of the present invention. As shown, a bit column 200 includes memory cells 205 and 210 connected to a multiplexor (MUX) circuit 235. Each cell within memory cells 205 and 210 corresponds to a single bit. Memory cells 205 are connected to MUX circuit 235 via a read bitline 215, and memory cells 210 are connected to MUX circuit 235 via a read bitline 220. MUX circuit 235 also receives two control input signals, namely, a local select 225 and a global select(0) 230. Similarly, a MUX circuit 240, which is controlled by local select 225 and a global select(1) 250, is connected to a second pair of memory cells (not shown) via a read bitline 255 and a read bitline 260. The outputs of MUX circuits 235 and 240 are combined to form an output 245 for data signal.

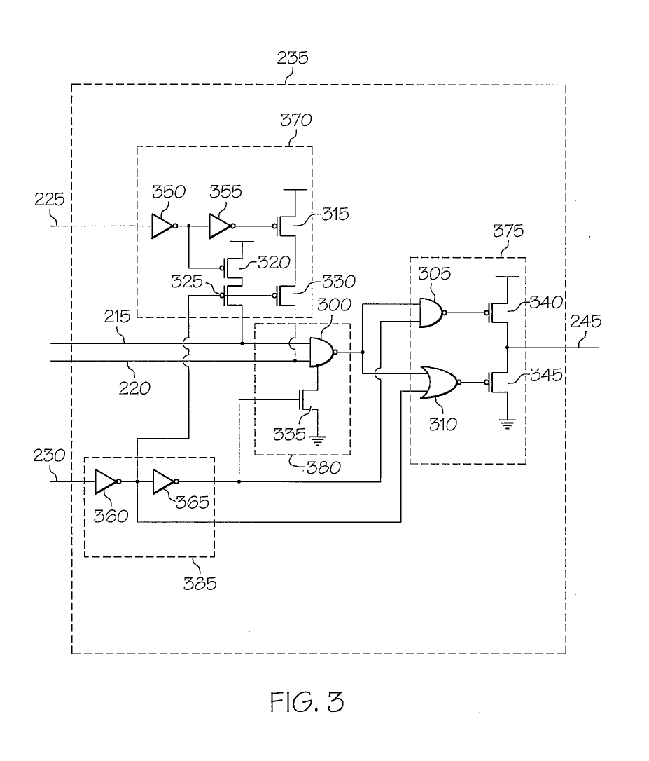

Since MUX circuits 235 and 240 are substantially identical to each other, only MUX circuit 235 will be further described. Referring now to FIG. 3, there is depicted a schematic diagram of MUX circuit 235, in accordance with a preferred embodiment of the present invention. As shown, MUX circuit 235 includes a local select processing module 370, a read bitline processing module 380, a global select processing module 385, and an output combination module 375.

Local select processing module 370 includes inverters 350 and 355, voltage pull up transistors 315 and 320, and voltage pull up disable transistors 325 and 330. Inverters 350 and 355 are connected in series to local select 225 (from FIG. 2). The gate of voltage pull up transistor 320 is connected to the output of inverter 350, and the gate of voltage pull up transistor 315 is connected to the output of inverter 355, such that the polarity of the input signals to voltage pull up transistors 315 and 320 are always opposite to each other, thereby enabling the voltage of either read bitline 215 or read bitline 220 to be pulled up at any time. Voltage pull up disable transistors 325 and 330 are connected to voltage pull up transistors 320 and 315, respectively, which are in turn connected to read bitline 215 and read bitline 220, respectively. Voltage pull up disable transistors 325 and 330 are connected to the output of inverter 360, thereby enabling global select 230 to be utilized to selectively disable the pull up (i.e., value increasing) capability of voltage control transistors 320 and 315, respectively.

Local select processing module 370 enables input signals from local select 225 and/or global select(0) 230 to selectively pull up the voltage of an input signal of either read bitline 215 or read bitline 220.

In an alternative embodiment, inverters 350 and 355 within local select processing module 370 can be substituted by two or more logical NAND gates (not shown). An input of each of the two or more logical NAND gates is connected to the output of inverter 365, rather than inverter 360. With the alternative embodiment, local select processing module 370 does not include voltage pull up disable transistors 325 and 330, the two or more logical NAND gates are utilized to selectively disable the pull up capability of voltage control transistors 320 and 315.

Read bitline processing module 380 includes a logical NAND gate 300 and an NAND gate disable transistor 335. Logical NAND gate 300 is a modified NAND gate containing multiple field effect transistors (FETs) that enable logical NAND gate 300 to receive input from NAND gate disable transistor 335 in addition to the conventional input points, which are coupled to read bitline 215 and read bitline 220. Global select(0) 230, which is coupled to NAND gate disable transistor 335, can thereby selectively disable the logical functionality of logical NAND gate 300, such that MUX circuit 235 will not produce output when read bitline 215 and read bitline 220 are allowed to float (i.e., not have an active input signal). As a result, power within bit column 200 (from FIG. 2) can be conserved by allowing bitlines to remain inactive when not being used (instead of constantly active as in the prior art).

Global select processing module 385 includes inverters 360 and 365, which are coupled to global select(0) 230 in series. The gate of NAND gate disable transistor 335 is connected to the output of inverter 365, and the gates of voltage pull up disable transistors 325 and 330 are connected to the output of inverter 360. Thus, inverter 360 changes the polarity of the voltage of the signal of global select(0) 230, such that the polarity of the input signals to voltage pull up disable transistors 325 and 330 is opposite to the polarity of the input signal of NAND gate disable transistor 335. Global select processing module 385 thereby enables the logical functionality of read bitline processing module 380 to be selectively disabled by local select processing module 370 and/or NAND gate disable transistor 335, according to the value of global select(0) 230.

Output combination module 375 includes a logical NAND gate 305, a logical NOR gate 310, and voltage control transistors 340 and 345. The inputs of logical NAND gate 305 are connected to the outputs of logical NAND gate 300 and inverter 365. The output of logical NAND gate 305 is connected to the gate of voltage control transistor 340. Similarly, the inputs of logical NOR gate 310 are connected to the outputs of logical NAND gate 300 and inverter 360. The output of logical NOR gate 310 is connected to gate of voltage control transistor 345. The node between voltage control transistors 340 and 345 provides data out 245 for output combination module 375.

As has been described, the present invention provides an apparatus for floating bitlines in SRAMs.

While the invention has been particularly shown and described with reference to a preferred embodiment, it will be understood by those skilled in the art that various changes in form and detail may be made therein without departing from the spirit and scope of the invention.

What is claimed is:

1. A static random access memory (SRAM) comprising:
a first SRAM cell column and a second SRAM cell column;
a first read bitline and a second read bitline; and
a multiplexor, which is coupled to said first and second SRAM cell columns via said first and second read bitlines, respectively, selectively transmits data from said first or second SRAM cell column via said first or second read bitline, respectively, to an output, wherein said multiplexor allows said first read bitline and/or said second read bitline to be remain uncharged when no data are being read from said first SRAM cell column and/or said second SRAM cell column.

2. The SRAM of claim 1, wherein said first SRAM cell column includes a plurality of SRAM cells.

3. The SRAM of claim 1, wherein said second SRAM cell column includes a plurality of SRAM cells.

4. The SRAM of claim 1, wherein said multiplexor includes a local select processing module, a read bitline processing module, a global select processing module, and an output combination module.

5. The SRAM of claim 4, wherein said local select processing module includes at least two inverters connected in series, a first voltage pull up transistor connected in series with a first voltage pull up disable transistor, and a second voltage pull up transistor connected in series with a second voltage pull up disable transistor.

6. The SRAM of claim 4, wherein said read bit line processing module includes a logical NAND gate and an NAND gate disable transistor.

7. The SRAM of claim 4, wherein said global select processing block includes at least two inverters connected in series, which are coupled to a global select line.

8. The SRAM of claim 4, wherein said output combination module a logical NAND gate, a logical NOR gate, and at least two voltage control transistors.
